(19) United States
(12) Patent Application Publication
(10) Pub. No.: US 2005/0005964 A1
(43) Pub. Date: Jan. 13, 2005

(54) Organic photoelectric conversion element

(76) Inventor: Takahiro Komatsu, Kasuga-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/885,132

(22) Filed: Jul. 7, 2004

(30) Foreign Application Priority Data
Jul. 9, 2003 (JP) P. 2003-194212

(51) Int. Cl. H01L 31/00

(52) U.S. Cl. 136/263; 136/256

(57) ABSTRACT

An organic photoelectric conversion element includes: at least two electrodes and a photoelectric conversion region made of at least one electron-donative organic material and one electron-accepting material provided between the electrodes on a substrate, wherein the visible light transmittance of the substrate is 85% or more or the product of the visible light transmittance of the substrate and one of the electrodes formed on the substrate is 80% or more. In this arrangement, external light can be efficiently taken in the photoelectric conversion region, making it possible to enhance the photoelectric conversion efficiency.

### BACKGROUND OF THE INVENTION

The present invention relates to an organic photoelectric conversion element utilizing a photovoltaic effect of an organic semiconductor material.

An organic photoelectric conversion element makes the use of the photovoltaic effect of an organic semiconductor material provided interposed between electrodes to supply electric power to the exterior of the element. This organic photoelectric conversion element is advantageous in that it can be produced at a lower energy cost than the related art photodiode comprising an inorganic semiconductor and gives little environmental burden when discarded and has been under study of practical use.

There are some types of organic photoelectric conversion elements. There have been proposed a wet type reported by Gratzel et al (see, e.g., Non-patent Reference 1), a laminated type (see, e.g., Non-patent Reference 2), a type having a mixture of electron-donating organic material and electron-accepting organic material (see, e.g., Non-patent Reference 3), etc.

The configuration of a related art organic photoelectric conversion element will be described hereinafter. FIG. 4 is a sectional view of an essential part of a related art organic photoelectric conversion element. In FIG. 4, the reference numeral 1 indicates a substrate, the reference numeral 2 indicates an anode, the reference numeral 3 indicates a photoelectric conversion region, the reference numeral 4 indicates an electron-donating layer made of an electron-donating organic material, the reference numeral 5 indicates an electron-donating layer made of an electron-accepting material, and the reference numeral 6 indicates a cathode.

As shown in FIG. 4, the organic photoelectric conversion element comprises an anode 2 made of a transparent electrically-conductive layer such as ITO formed on a light-transmitting substrate 1 such as glass by a sputtering method, resistance-heated vacuum metallizing method or the like, a photoelectric conversion region 3 comprising an electron-donating layer 4 and an electron-accepting layer 5 formed on the anode 2 by a resistance-heated vacuum metallizing method or the like and a cathode 6 made of metal formed on the top of the photoelectric conversion region 3 by a resistance-heated vacuum metallizing method or the like.

When irradiated with light, the organic photoelectric conversion element having the aforementioned arrangement allows the photoelectric conversion region 3 to absorb light to form exciters. Subsequently, carriers are separated from the photoelectric conversion region 3. Electrons move to the cathode 6 through the electron-accepting layer 5 while positive holes move to the anode 2 through the electron-accepting layer 4. In this manner, electromotive force occurs across both the electrodes. When the organic photoelectric conversion element is connected to an external circuit, electric power can be taken out.

[Non-Patent Reference 1]

M. K. Nazeeruddin, a, Kay, I. Rodicio, R. Humphry-Baker, E. Mueller, P. Liska, N. Vlachopoulos, M, Graetzel, “Journal of the American Chemical Society”, 115, 1993, pp. 6,382-6,390

[Non-Patent Reference 2]

P. Peumans, S. R. Forrest, “Applied Physics Letters”, 79, 2001, pp. 126-128

[Non-Patent Reference 3]

G. Yu, J. Gao, J. C. Hummelen, F. Wudl, A. J. Heeger, “Science”, 270, 1995, pp. 1,789-1,791

Since an organic photoelectric conversion element is a device which converts incident optical energy to electric energy as previously mentioned, it is necessary that light be taken into the interior of the element in a larger amount to enhance its conversion efficiency. In an ordinary organic photoelectric conversion element, external light must pass through at least the substrate and one electrode until it reaches the photoelectric conversion region. Therefore, when light is reflected or absorbed by the substrate or electrode, the amount of light which reaches the photoelectric conversion region is reduced, causing the deterioration of conversion efficiency.

The surface profile of the substrate and the electrode formed on the top thereof, too, is very important. The photoelectric conversion region of an organic photoelectric conversion elements is often prepared by a spin coating method, dipping method or printing method. However, these wet processes are more subject to the effect of underlying layer than dry processes such as vacuum metallizing. In particular, in the case where the spin coating method is employed, when protrusions are present on the area to be coated, the resulting coat layer has a reduced thickness at the area having protrusions. Further, no film can be formed in the vicinity of protrusions, causing fatal defectives.

Further, the related art photoelectric conversion elements are all formed on a rigid substrate such as silicon wafer and glass and thus can be difficultly deformed into an arbitrary shape or disposed on an arbitrary shape.

### SUMMARY OF THE INVENTION

The invention gives solution to the aforementioned problems. An aim of the invention is to provide a high efficiency and reliability easily-deformable organic photoelectric conversion element by optimizing the optical properties of the substrate to be incorporated in the organic photoelectric conversion element, the surface profile of the substrate and electrode used, the temperature and mechanical properties of the substrate, etc.

The organic photoelectric conversion element of the invention comprises at least two electrodes and a photoelectric conversion region made of at least one electron-donative organic material and one electron-accepting material provided between the electrodes on a substrate, wherein the substrate and the electrodes have an enhanced light transmittance. In this arrangement, the amount of light which can reach the photoelectric conversion region can be raised, making it possible to provide a high efficiency organic photoelectric conversion element.

Further, the organic photoelectric conversion element of the invention is intended to provide the substrate and/or the electrodes formed on the substrate with an optimized surface profile. In this arrangement, an organic photoelectric conversion element having a high reliability can be provided at a high yield.

Moreover, in accordance with the invention, a photoelectric conversion element is formed on a flexible substrate, making it possible to obtain an organic photoelectric conversion element which can be easily deformed.

### BRIEF DESCRIPTION OF THE DRAWINGS

FIG. 1 is a sectional view of an essential part of an organic photoelectric conversion element according to an embodiment of implementation of the invention;

FIG. 2 is a sectional view of an essential part of an organic photoelectric conversion element according to another embodiment of implementation of the invention;

FIG. 3 is a sectional view of an essential part of an organic photoelectric conversion element according to a further embodiment of implementation of the invention; and

FIG. 4 is a sectional view of an essential part of a related art organic photoelectric conversion element.

### DETAILED DESCRIPTION OF THE PREFERRED EMBODIMENTS

According to first aspect of the invention, an organic photoelectric conversion element comprises: at least two electrodes and a photoelectric conversion region made of at least one electron-donative organic material and one electron-accepting material provided between the electrodes on a substrate, wherein the visible light transmittance of the substrate is 85% or more or the product of the visible light transmittance of the substrate and one of the electrodes formed on the substrate is 80% or more. In this arrangement, external light can be efficiently taken in the photoelectric conversion region, making it possible to enhance the photoelectric conversion efficiency.

According to second aspect of the invention, an organic photoelectric conversion element comprises: at least two electrodes on a substrate; and a photoelectric conversion region provided between the electrodes, having at least one electron-donating organic material and one electron-accepting material, wherein the maximum light transmittance of the substrate and one of the electrodes formed on the substrate are each 85% or more and the maximum light transmittance of the electrode substrate comprising the substrate and one of the electrodes formed on the substrate in combination is 80% or more. In this arrangement, external light can be efficiently taken in the photoelectric conversion region, making it possible to enhance the photoelectric conversion efficiency.

According to third aspect of the invention, an organic photoelectric conversion element comprises: at least two electrodes on a substrate; and a photoelectric conversion region provided between the electrodes, having at least one electron-donating organic material and one electron-accepting material, wherein the haze of the substrate is 30% or less. In this arrangement, external light can be efficiently taken in the photoelectric conversion region, making it possible to enhance the photoelectric conversion efficiency. The haze as defined herein may be total haze of the substrate having a film laminated on the outer surface thereof, not to mention substrate in single form.

According to fourth aspect of the invention, an organic photoelectric conversion element comprises: at least two electrodes on a substrate; and a photoelectric conversion region provided between the electrodes, having at least one electron-donating organic material and one electron-accepting material, wherein the refractive index of the substrate increases toward the direction of transmission of light from the direction of incidence of light. In this arrangement, the fresnel reflection occurring when light enters in the electrodes from the substrate can be reduced to increase the amount of light reaching the photoelectric conversion region, making it possible to provide a high efficiency organic photoelectric conversion element. A laminate of materials having different refractive indexes provided on the substrate in such an arrangement that the refractive index gradually increases along the thickness of the laminate may be used, not to mention a substrate which itself has a gradient of refractive index.

According to fifth aspect of the invention, an organic photoelectric conversion element comprises: at least two electrodes on a substrate; and a photoelectric conversion region provided between the electrodes, having at least one electron-donating organic material and one electron-accepting material, wherein the substrate is flexible. In this arrangement, an organic photoelectric conversion element which can be deformed into various shapes and thus has a high degree of freedom of selection of installation site can be provided.

According to sixth aspect of the invention, the organic photoelectric conversion element, wherein the flexible substrate is made of a light-transmitting organic material. In this arrangement, a substrate having high light transmission properties and flexibility can be obtained, making it possible to provide a high efficiency flexible organic photoelectric conversion element.

According to seventh aspect of the invention, an organic photoelectric conversion element comprises: at least two electrodes on a substrate; and a photoelectric conversion region provided between the electrodes, having at least one electron-donating organic material and one electron-accepting material, wherein the substrate is impermeable to light in the ultraviolet range. In this arrangement, the various constituents of the organic photoelectric conversion element made of an organic material can be prevented from being deteriorated by ultraviolet rays, making it possible to drastically prolong the electricity generation life of the organic photoelectric conversion element.

The term “light in the ultraviolet range” as used herein is meant to indicate light in the wavelength range of 300 nm or less. The term “impermeability to light in the ultraviolet range” as used herein is meant to indicate that the material absorbs or reflects at least part of light in the above defined range. A structure comprising other ultraviolet-absorbing materials or the like provided on the substrate may be used, not to mention a substrate which is itself impermeable to light in the ultraviolet range.

According to eighth aspect of the invention, an organic photoelectric conversion element comprises: at least two electrodes on a substrate; and a photoelectric conversion region provided between the electrodes, having at least one electron-donating organic material and one electron-accepting material, wherein the substrate is resistant to exposure to ultraviolet rays. In this arrangement, the deterioration of the substrate by ultraviolet rays can be prevented to allow prolonged stable generation of electricity, making it possible to prolong the life of the organic photoelectric conversion element.

A structure having other ultraviolet-absorbing materials disposed on the surface of the substrate or thereinside may be used, not to mention a substrate which itself is resistant to exposure to ultraviolet rays.

According to ninth aspect of the invention, an organic photoelectric conversion element comprises: at least two electrodes on a substrate; and a photoelectric conversion region provided between the electrodes, having at least one electron-donating organic material and one electron-accepting material, wherein the maximum height Rmax (JIS B 0601) of the surface roughness of the substrate and/or the electrodes formed on the substrate is 100 nm or less. In this arrangement, protrusions greater than the thickness of the photoelectric conversion region can be eliminated to prevent the generation of shortcircuit current, making it possible to provide an organic photoelectric conversion element having a high conversion efficiency.

According to tenth aspect of the invention, an organic photoelectric conversion element comprises: at least two electrodes on a substrate; and a photoelectric conversion region provided between the electrodes, having at least one electron-donating organic material and one electron-accepting material, wherein the arithmetic average roughness Ra of the surface of the substrate and/or the electrodes formed on the substrate is from 0.01 nm to 10 nm. In this arrangement, the generation of shortcircuit current can be prevented, making it possible to provide an organic photoelectric conversion element having a high conversion efficiency.

According to eleventh aspect of the invention, an organic photoelectric conversion element comprising: at least two electrodes on a substrate; and a photoelectric conversion region provided between the electrodes, having at least one electron-donating organic material and one electron-accepting material, wherein the total number of foreign matters, depression, etc. having a diameter of 1 μm or more on the surface of the substrate and/or the electrodes formed on the substrate is 100 or less per m². In this arrangement, the number of foreign matters which perform no photoelectric conversion and hence make no contribution to electricity generation can be eliminated, making it possible to obtain an organic photoelectric conversion element having a high conversion efficiency which is so reliable that the entrance of water content or the like from foreign matters can be prevented.

According to twelfth aspect of the invention, an organic photoelectric conversion element comprising: at least two electrodes on a substrate; and a photoelectric conversion region provided between the electrodes, having at least one electron-donating organic material and one electron-accepting material, wherein the total number of foreign matters, depression, etc. having a diameter of 1 μm or more on the surface of the substrate and/or the electrodes formed on the substrate is 100 or less per m². In this arrangement, water content adsorbed by or contained in the surface and interior of the substrate can be removed, making it possible to provide an organic photoelectric conversion element capable of generating electricity in a stable manner over an extended period of time. The heat treatment is preferably effected at a temperature of not higher than the glass transition temperature of the substrate material. If necessary, the heat treatment may be effected under reduced pressure.

According to thirteenth aspect of the invention, an organic photoelectric conversion element comprising: at least two electrodes on a substrate; and a photoelectric conversion region provided between the electrodes, having at least one electron-donating organic material and one electron-accepting material, wherein the glass transition point of the substrate is 80° C. or more. In this arrangement, the temperature at which the substrate is subjected to heat treatment before the formation of the organic photoelectric conversion element can be raised, making it possible to effectively remove water content from the substrate. Further, since the substrate is excellent in heat resistance, the resulting organic photoelectric conversion element can be used in various atmospheres. Thus, the organic photoelectric conversion element of the invention can maintain optimum electricity-generating properties.

According to fourteenth aspect of the invention, an organic photoelectric conversion element comprising: at least two electrodes on a substrate; and a photoelectric conversion region provided between the electrodes, having at least one electron-donating organic material and one electron-accepting material, wherein the deflection temperature under load (DTUL) (=softening temperature) of the substrate is 60° C. or more. In this arrangement, the substrate exhibits an excellent heat treatment, making it possible to provide an organic photoelectric conversion element which can be used in various atmospheres. Thus, the organic photoelectric conversion element of the invention can maintain optimum electricity-generating properties.

According to fifteenth aspect of the invention, an organic photoelectric conversion element comprising: at least two electrodes on a substrate; and a photoelectric conversion region provided between the electrodes, having at least one electron-donating organic material and one electron-accepting material, wherein the substrate exhibits a tensile strength (JIS K 6911) of 30 N·mm⁻² or more and a maximum elongation (JIS K 7113) of 50% or more. In this arrangement, the resulting organic photoelectric conversion element can be easily subjected to deformation such as stretching and bending and thus can perform electricity generation in arbitrary form in various places.

According to sixteenth aspect of the invention, an organic photoelectric conversion element comprising: at least two electrodes on a substrate; and a photoelectric conversion region provided between the electrodes, having at least one electron-donating organic material and one electron-accepting material, wherein the outer surface of the substrate is hydrophilicized. In this arrangement, the deterioration of various constituents of the organic photoelectric conversion element by lens effect can be prevented, making it possible to maintain optimum electricity-generating properties.

According to seventeenth aspect of the invention, an organic photoelectric conversion element comprises: at least two electrodes on a substrate; and a photoelectric conversion region provided between the electrodes, having at least one electron-donating organic material and one electron-accepting material, wherein the electron-accepting material comprises fullerenes and/or carbon nanotubes incorporated therein. In this arrangement, electrons can move from the electron-donative organic material to the electron-accepting material at a very high rate to efficiently generate carriers, making it possible to provide a high efficiency organic photoelectric conversion element.

According to eighteenth aspect of the invention, an organic photoelectric conversion element comprises: at least two electrodes on a substrate; and a photoelectric conversion region provided between the electrodes, having at least one electron-donating organic material and one electron-accepting material, wherein the electron-donating organic material and the electron-accepting material are provided in admixture. In this arrangement, the spreading of a mixed solution makes it easy to prepare a photoelectric conversion region and thus makes it possible to provide an organic photoelectric conversion element having a greater area at a reduced cost.

The organic photoelectric conversion element of the invention will be further described hereinafter.

The substrate to be used in the organic photoelectric conversion element of the invention is not specifically limited so far as it has a desired mechanical and thermal strength and can effectively transmit radiation.

For example, a material having a high transparency to rays in the visible light range such as glass, polyethylene terephthalate, polycarbonate, polymethyl methacrylate, polyether sulfon, polyvinyl fluoride, polypropylene, polyethylene, polyacrylate, amorphous polyolefin and fluororesin may be used. Alternatively, a flexible substrate obtained by forming such a material into a film may be used. A polymer material, if used as a substrate, may have a film made of various metals or metal oxides provided on the outer surface thereof to such an extent that the transmittance cannot be impaired as much as possible to advantage for the purpose of enhancing the moisture resistance thereof.

As the substrate material there may be used a material which transmits only light in a specific wavelength range or a material having a photo-photo conversion performance capable of converting light received to light in a specific wavelength range depending on the purpose. The substrate is preferably insulating but is not necessarily needed to be insulating and may be electrically conductive so far as the operation of the organic photoelectric conversion element cannot be prevented or depending on the purpose.

At least one of the electrodes of the organic photoelectric conversion element needs to transmit light. The transmittance of the electrodes has a great effect on the photoelectric conversion properties. Therefore, as an anode for the aforementioned organic photoelectric conversion element there is used an electrode generally called “transparent electrode” formed by subjecting ITO, ATO (SnO₂ doped with Sb), AZO (ZnO doped with Al) or the like to sputtering, ion beam vacuum evaporation or the like.

The juxtaposition or otherwise provision of an auxiliary electrode makes it possible to use a thin film of various metals such as Au and Ag, relatively high resistivity ITO coat or various electrically-conductive polymer compounds such as PEDOT, PPV and polyfluorene as an electrode.

As the electron-donative organic material there may be used a polymer such as phenylene vinylene, fluorene, carbazole, indole, pyrene, pyrrole, picoline, thiophene, acetylene and diacetylene or derivative thereof. The electron-donative organic material is not limited to polymers. Other examples of the electron-donative organic material employable herein include porphyrinated compounds such as porphyrin, tetraphenylporphyrin copper, phthalocyanine, copper phthalocyanine and titanium phthalocyanine oxide, aromatic tertiary amines such as 1,1-bis{4-(di-P-tollylamino)phenyl}cyclohexane, 4,4′,4″-trimethyl triphenylamine, N,N,N′,N′-tetrakis(P-tollyl)-P-phenylenediamine, 1-(N,N-di-P-tollylamio)naphthalene, 4,4′-bis(dimethylamino)-2-2′-dimethyltriphenyl methane, N,N,N′,N′-tetraphenyl-4,4′-diaminobiphenyl, N,N′-diphenyl-N,N′-di-m-tollyl-4,4′-diaminobiphenyl and N-phenylcarbazole, stilbene compounds such as 4-di-P-tollylaminostilbene and 4-(di-P-tollylamino)-4′-[4-(di-P-tollylamino)styryl]stilbene, triazole derivatives, oxadiazole derivatives, imidazole derivatives, polyarylalkane derivatives, pyrazoline derivatives, pyrazolones derivatives, phenylenediamine derivatives, anylamine derivatives, amino-substituted chalcone derivatives, oxazole derivatives, styrylanthracene derivatives, fluorenone derivatives, hydrazone derivatives, silazalane derivatives, polysilane-based aniline copolymers, polymer aligomers, styrylamine compounds, aromatic dimethylidene-based compounds, and poly-3-methylthiophene.

As the electron-accepting material there may be used fullerene such as C60 and C70, carbon nanotube, derivative thereof, oxadiazole derivative such as 1,3-bis(4-tert-butylphenyl-1,3,4-oxadiazolyl)phenylene (OXD-7), anthraquinonedimethane derivative, diphenylquinone derivative or the like.

As the cathode there may be used any material which can efficiently take electric charge generated out of the circuit. In some detail, a metal such as Al, Au, Cr, Cu, In, Mg, Ni, Si and Ti, Mg alloy such as Mg—Ag alloy and Mg—In alloy, Al alloy such as Al—Li alloy, Al—Sr alloy and Al-Ba alloy or the like may be used. In order to eliminate the generation of shortcircuit current, an approach is preferably used involving the introduction of a metal oxide, metal fluoride or the like between the organic layer and the cathode.

The preparation of the organic photoelectric conversion element from these materials may be carried out by any vacuum process such as vacuum evaporation and sputtering or any wet process such as spin coating and dipping. The preparation method may be arbitrarily selected according to the material used, the structure of the organic photoelectric conversion element, etc.

Embodiments of implementation of the invention will be described hereinafter.

(Embodiment 1)

An organic photoelectric conversion element according to an embodiment of implementation of the invention will be described hereinafter.

The configuration of the organic photoelectric conversion element according to the present embodiment of implementation of the invention is the same as that of the related art organic photoelectric conversion element shown in FIG. 4.

The organic photoelectric conversion element of the invention is different from the related art technique in that the visible light transmittance of the substrate 1 and one (anode 2) of the electrodes formed thereon are each 80% or more, the maximum light transmittance of the substrate 1 and one (anode 2) of the electrodes formed thereon each are 85% or more, the maximum light transmittance of the electrode substrate (substrate 1 and anode 2) having in combination the substrate 1 and one of the electrodes formed thereon is 80% or more and the haze of the substrate 1 is 30% or less.

In an ordinary organic photoelectric conversion element, light received passes through the substrate 1 and the anode 2 and then reaches the photoelectric conversion region 3. Only the light which has reached the photoelectric conversion region 3 contributes to the generation of electricity. Therefore, the enhancement of the light transmittance of the substrate 1 and the electrode such as anode 2 makes it possible to improve the photoelectric conversion efficiency.

In the case where the organic photoelectric conversion element is used as, e.g., a solar cell, light beam with which the organic photoelectric conversion element is irradiated is sunlight. The sunlight has a wide spectrum ranging from ultraviolet to infrared. Since the organic material can absorb light mainly in the visible light range, a very important key to enhancement of the efficiency of solar cell is how efficiently the light in the visible light range is allowed to reach the photoelectric conversion region where it is then absorbed.

As ITO film to be used in an ordinary organic photoelectric conversion element, ITO film having a low resistivity is often formed to efficiently take carriers out of the element. In this case, the laminate has a visible light transmittance as low as about 80% with respect to light in the wavelength of 550 nm and a drastically reduced transmittance with respect to light in the wavelength of around 400 nm due to absorption by ITO. Accordingly, the laminate exhibits a transmittance of lower than 80% with respect to light in the whole visible light range of from 400 nm to 700 nm. Thus, it is the status of quo that sunlight cannot be effectively introduced into the photoelectric conversion region.

In order to enhance the visible light transmittance of the substrate and the electrode, it is useful to change the thickness of the substrate and the electrode, not to mention the formulation of the constituents of the organic photoelectric conversion element. In the case where various glass or polymer materials are used to prepare the substrate, it is necessary that particular attention be given to mechanical strength. However, by predetermining the thickness of the substrate to 1.2 mm or less, a high visible light transmittance can be realized. The reduction of the thickness of the electrode is not desirable from the standpoint of transportation of carriers. However, the juxtaposition or otherwise provision of an auxiliary electrode allows the reduction of the thickness of the electrode without affecting the transportation of carriers. In this arrangement, the visible light transmittance of the substrate and the electrode can be enhanced. However, when the product of the visible light transmittance of the substrate and the electrode is less than 80%, it is made difficult to enhance the photoelectric conversion efficiency drastically from that of the related art technique. However, the enhancement of the visible light transmittance of the substrate and the electrode causes the increase of the amount of not only light which enters directly in the photoelectric conversion region but also light which is reflected by the back electrode and then again enters in the photoelectric conversion region. Accordingly, the higher the transmittance of the substrate and the electrode is, the greater is the contribution to the photoelectric conversion properties. In some detail, when the product of the visible light transmittance of the substrate and the electrode is 80% or more, the conversion efficiency of the organic photoelectric conversion element can be drastically enhanced.

In the case where the organic photoelectric conversion element is used as a sensor which receives only light in a specific wavelength range, the substrate and the electrode merely have to efficiently transmit the light in a specific wavelength range. This arrangement, too, can be realized by the reduction of the thickness of the substrate and the electrode. In this case, too, the maximum light transmittance of the substrate and the electrode in combination can be predetermined to 80% or more, making it possible to drastically enhance the conversion efficiency.

In the case where the organic photoelectric conversion element is used as a sensor, it is also important to suppress the expansion of incident light. To this end, the haze of the substrate can be reduced to eliminate the scattering of light. When the haze of the substrate is greater than 30%, the scattering of light cannot be neglected. The organic photoelectric conversion element, if used a position sensor or the like, cannot provide accurate date or causes like troubles. On the contrary, when the haze of the substrate is 30% or less, the scattering of light can be mostly inhibited, making it possible to provide various sensors having a high reliability.

While the present embodiment has been described with reference only to the case where the organic photoelectric conversion element receives light on the substrate side thereof, the light transmittance of the substrate is not questioned if light is received on the side opposite the substrate. In this case, the light transmittance of the electrode on the light-receiving side such as cathode is important. It is essential for the realization of a high efficiency organic photoelectric conversion element that the electrode have the same light transmittance as that of the substrate of the invention.

(Embodiment 2)

An organic photoelectric conversion element according to another embodiment of implementation of the invention will be described hereinafter.

The configuration of the organic photoelectric conversion element according to the present embodiment of implementation of the invention is the same as that of the related art organic photoelectric conversion element shown in FIG. 4.

The organic photoelectric conversion element of the invention is different from the related art technique in that the refractive index of the substrate increases toward the direction of transmission of light from the direction of incidence of light.

In the related art organic photoelectric conversion element having the configuration shown in FIG. 4, external light passes through the substrate 1, the anode 2 and the photoelectric conversion region 3 in this order. Among these components, the anode 2 made of ITO or the like normally has the highest refractive index. Since the difference in refractive index between the substrate land the anode 2 is great, the resulting fresnel reflection on the interface of the substrate 1 with the anode 2 causes loss of incident light.

The invention is intended to provide the substrate with a refractive index gradient in the thickness direction such that the gradient gradually increases toward the transmission side, i.e., anode from the light incidence side to minimize the loss of incident light.

In this arrangement, the fresnel reflection on the interface of the substrate with the anode can be eliminated, making it possible to provide a high efficiency organic photoelectric conversion element.

The refractive index gradient can be obtained, e.g., by adding BaO or the like sequentially in the direction of thickness of glass.

The refractive index gradient may be provided by laminating a plurality of materials having different refractive indexes, not to mention the aforementioned case where the substrate itself has a refractive index gradient.

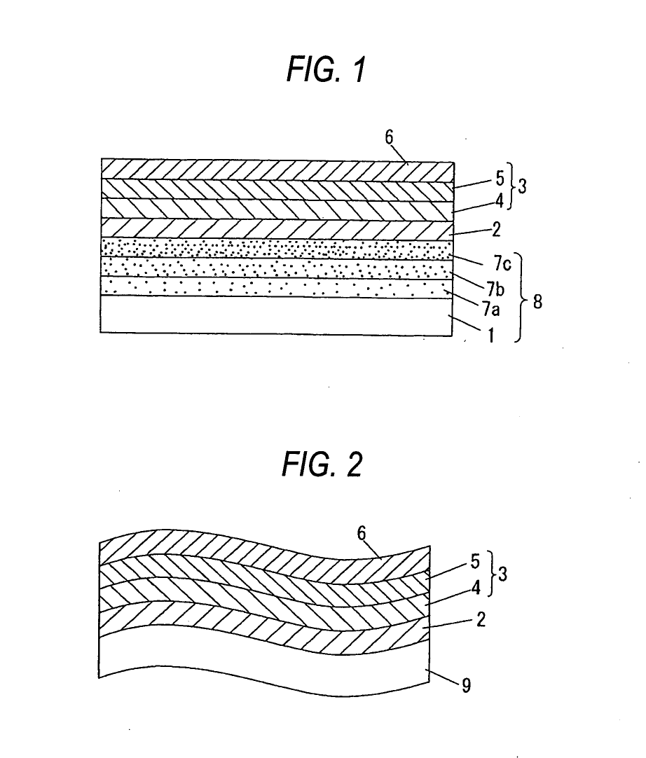

FIG. 1 is a sectional view of an essential part of an organic photoelectric conversion element according to an embodiment of implementation of the invention. This organic photoelectric conversion element has the same configuration as the related art configuration except that it has thin optical films 7a, 7b and 7c. These thin optical films are laminated in such an arrangement that the refractive index increases in the order of 7a<7b<7c. The substrate 1 and the thin optical films 7a, 7b and 7c are laminated to form a substrate 8 for organic photoelectric conversion element.

The thin optical film 7a has a refractive index close to that of the substrate and the thin optical film 7c has a refractive index close to that of the anode 2.

These thin optical films 7a, 7b and 7c may be each formed by a methyl polymethacrylate, polystyrene, polyvinyl carbazole or the like.

In accordance with the aforementioned configuration that the refractive index gradually increases, light loss due to fresnel reflection is less than in the configuration that light is incident directly on the anode from the substrate 1, making it possible to provide a high efficiency organic photoelectric conversion element.

(Embodiment 3)

An organic photoelectric conversion element according to a further embodiment of implementation of the invention will be described hereinafter.

FIG. 2 is a sectional view of an essential part of an organic photoelectric conversion element according to a further embodiment of implementation of the invention. The configuration of this organic photoelectric conversion element is the same as that of the related art in that it has an anode 2, a photoelectric conversion region 3 and a cathode 6. The organic photoelectric conversion element according to the present embodiment is different from the related art in that the substrate 9 is flexible.

The related art organic photoelectric conversion elements are formed on glass and thus are not flexible and cannot be freely deformed. Therefore, the place where the related art organic photoelectric conversion elements are installed is limited, possibly preventing the spread of organic photoelectric conversion elements. However, since organic photoelectric conversion elements are all formed by organic and inorganic thin film materials except the substrate and thus have a relatively high flexibility, these devices can be provided with flexibility themselves merely by using a flexible substrate.

The invention gives solution to this problem and is intended to provide a flexible organic photoelectric conversion element by making the substrate 9 from a polymer film such as polycarbonate and polyethylene terephthalate. The substrate can be provided with flexibility also by reducing the thickness of the related art glass substrate or using a laminate film of glass with an organic material.

(Embodiment 4)

An organic photoelectric conversion element according to a further embodiment of implementation of the invention will be described hereinafter.

The configuration of the organic photoelectric conversion element according to the present embodiment is the same as shown in FIG. 4. The organic photoelectric conversion element according to the present embodiment is different from the related art organic photoelectric conversion element in that the substrate 1 is impermeable to light in the ultraviolet range and resistant to exposure to ultraviolet rays. An organic photoelectric conversion element comprises a photoelectric conversion region formed by an organic material. Therefore, when the photoelectric conversion region is exposed to light in the ultraviolet range contained in radiation or external light over an extended period of time or in a large amount, this organic material undergoes photo-deterioration, resulting in the drop of photoelectric conversion efficiency.

However, when the substrate 1 itself is impermeable to light in the ultraviolet range and resistant to exposure to ultraviolet rays as defined in the invention, ultraviolet rays can be prevented from reaching the organic material, making it possible to maintain a stable photoelectric conversion efficiency over an extended period of time. The same effect can be exerted also by providing an ultraviolet-absorbing material or the like on the outer surface of the substrate.

As the substrate 1 having impermeability to light in the ultraviolet range and resistance to ultraviolet rays there may be used a polymethyl methacrylate, polycarbonate or the like besides glass as used in the related art technique.

(Embodiment 5)

An organic photoelectric conversion element according to a further embodiment of implementation of the invention will be described hereinafter.

The configuration of the organic photoelectric conversion element according to the present embodiment is the same as shown in FIG. 4. The organic photoelectric conversion element according to the present embodiment is different from the related art organic photoelectric conversion element in that the maximum height Rmax (JIS B 0601) of the surface roughness of the substrate 1 and/or the electrode (anode 2) formed on the substrate is 100 nm or less, the arithmetic average roughness Ra of the surface of the substrate 1 and/or the electrode (anode 2) formed on the substrate is from 0.01 nm to 10 nm and the total number of foreign matters, depression, etc. having a diameter of 1 μm or more on the surface of the substrate 1 and/or the electrode (anode 2) formed on the substrate is 100 or less per m².

The profile of the surface of the substrate 1 and the photoelectric conversion properties have an extremely close relation to each other. In general, the photoelectric conversion region 3 of the organic photoelectric conversion element is formed on an electrode such as anode 2 disposed on the substrate 1. The formation of the photoelectric conversion region 3 is carried out by any method such as vacuum evaporation, spin coating, dipping and spraying. Whatever method is used, the resulting film reflects the profile of the underlying substrate land electrode (anode 2). In particular, when rises, protrusions and defects greater than the thickness of the photoelectric conversion region 3 formed on the electrode are present, their effect are remarkable. The effect is particularly remarkable with spin coating method or dipping method, which can be conducted at a reduced cost. For example, when the substrate or electrode has a rough surface or defects, fatal device defectives can occur such as generation of area on which no film can be formed.

For example, an ordinary organic photoelectric conversion element comprises a photoelectric conversion region having a thickness of about 100 nm formed on the electrode substrate. Therefore, in the case where the photoelectric conversion region is formed by spin coating or doctor blade method, when Rmax (JIS B 0601) of the substrate is greater than 100 nm, the photoelectric conversion region can be difficultly formed on that area, causing defects. When these defects occur, the resulting organic photoelectric conversion element cannot perform photoelectric conversion in some cases. It is therefore necessary that Rmax of the substrate be sufficiently controlled. The reduction of Rmax is preferably carried out by polishing the surface of the substrate or electrode or by providing an undercoat layer made of SiO₂ or the like interposed between the electrode and the substrate.

The arithmetic average roughness Ra is very important for the enhancement of photoelectric conversion properties. It is known that the material of the photoelectric conversion region has a great effect on the photoelectric conversion efficiency of the organic photoelectric conversion element. As previously mentioned, the photoelectric conversion region is formed by spin coating method or the like. Therefore, the material of the photoelectric conversion region differs greatly with the arithmetic average roughness Ra of the underlying electrode substrate. When Ra is less than 10 nm, the photoelectric conversion region can be formed in a stable form. The smaller Ra is, the better is the stability of the photoelectric conversion region. The reduction of Ra can be realized by polishing the surface of the substrate or electrode or by providing an undercoat layer made of SiO₂ or the like interposed between the electrode and the substrate as in the reduction of Rmax. However, since the reduction of Rmax to less than 0.01 nm causes cost rise, it is practical that the lower limit of Rmax is 0.01 nm.

The presence of foreign matters having a size of 1 μm or more on the surface of the substrate or electrode causes device defects as in Rmax. However, the reduction of the number of foreign matters having a size of 1 μm or more to 100 or less per m² makes it possible to form an organic photoelectric conversion element having a high reliability in a high yield. When the number of foreign matters having a size of 1 μm or more is 100 or less per m², the yield of preparation of a photoelectric conversion element having a size of 1 cm square is 99% or more, which is sufficiently acceptable. In the case where a large-sized organic photoelectric conversion panel is prepared, too, when the number of foreign matters having a size of 1 μm or more is 100 or less per m², the effect of defects can be easily eliminated by dividing the panel into small regions.

Thus, in the invention, the aforementioned problem can be solved by smoothing the surface profile of the substrate 1 and/or electrode formed on the substrate 1 to eliminate protrusions in particular, making it possible to form an organic photoelectric conversion element having a high efficiency and a high reliability.

(Embodiment 6)

An organic photoelectric conversion element according to a further embodiment of implementation of the invention will be described hereinafter.

In the present embodiment, too, the configuration of the organic photoelectric conversion element is the same as shown in FIG. 4.

The organic photoelectric conversion element according to the present embodiment is different from the related art in that the substrate exhibits a glass transition point of 80° C. or more and a deflection temperature under load (DTUL) (=softening temperature) of 60° C. or more.

In the related art organic photoelectric conversion element, the electrodes and the photoelectric conversion region are formed directly on the substrate. Therefore, when the substrate has so poor a thermal stability that it softens and deforms, the overlying electrodes or photoelectric conversion region cannot follow the deformation, possibly causing fatal element defects.

The thermal stability of the substrate is important also for the purpose of heating the substrate to remove water content during the preparation of element.

To this end, the heat resistance of the substrate is enhanced in the invention. In some detail, the glass transition point of the substrate is defined. The removal of water content from the substrate is carried out by vacuum drying. In order to completely remove water content, it is necessary that the substrate be heated to 80° C. or more even in vacuo. Accordingly, it is essential that the glass transition point of the substrate is 80° C. or more. When the softening temperature of the substrate is less than 60° C., the working atmosphere of the element is drastically limited, making it difficult to use the element outdoor or in vehicles. When the softening temperature of the substrate is 60° C. or more, the element can be used in various atmospheres.

The thermal stability of the substrate is very important factor in the case where the substrate is made of a polymer material. The enhancement of the heat resistance of the substrate makes it possible to provide an organic photoelectric conversion element which exhibits a high reliability even in a high temperature range. As such a polymer material there is preferably used a polyethylene terephthalate, polymethyl methacrylate or polycarbonate, which exhibits a relatively high heat resistance.

(Embodiment 7)

An organic photoelectric conversion element according to a further embodiment of implementation of the invention will be described hereinafter.

The configuration of the organic photoelectric conversion element according to the present embodiment is the same as shown in FIG. 4. The organic photoelectric conversion element according to the present embodiment is different from the related art organic photoelectric conversion element in that the substrate exhibits a tensile strength (JIS K 6911) of 30 N·mm⁻² or more and a maximum elongation (JIS K 7113) of 50% or more.

One of the characteristics of organic photoelectric conversion elements is that the device can be rendered flexible. In order to actually deform the organic photoelectric conversion element into an arbitrary form, it is necessary that the substrate be flexible as well as tough.

A substrate having a tensile strength (JIS K 6911) of 30 N·mm⁻² or more and a maximum elongation (JIS K 7113) of 50% or more can be freely bent without undergoing necking. However, a substrate which doesn't meet either of these requirements can easily undergo necking leading to clouding. Therefore, a substrate made of a polycarbonate or polymethyl methacrylate having a great tensile strength and maximum elongation is used in the present embodiment. In this arrangement, the element can be deformed into an arbitrary form without impairing its photoelectric conversion properties.

However, the electrode itself can easily undergo severance depending on its composition or under some film-forming conditions. Thus, it is, of course, absolutely necessary that the element be deformed before use in such an arrangement that it undergoes no such severance.

(Embodiment 8)

An organic photoelectric conversion element according to a further embodiment of implementation of the invention will be described hereinafter.

The configuration of the organic photoelectric conversion element according to the present embodiment is the same as shown in FIG. 4. The organic photoelectric conversion element according to the present embodiment is different from the related art organic photoelectric conversion element in that the outer surface of the substrate is subjected to hydrophilicization.

Organic photoelectric conversion elements can be used in various atmospheres and thus are expected to be used outdoor or in a high humidity atmosphere. In this usage, when the contact angle of the outer surface of the substrate with respect to water is great, external light is converged in the layers constituting the element, causing local temperature rise or other defectives leading to the deterioration of the organic material. As a result, the photoelectric conversion efficiency of the organic photoelectric conversion element can be deteriorated.

In accordance with the invention, the hydrophilicization of the outer surface of the substrate causes the reduction of the contact angle of the outer surface of the substrate with respect to water, making it possible to provide an organic photoelectric conversion element having a high reliability which is little subject to deterioration by external light. This hydrophilicization is effective particularly when a resin-based substrate having a great contact angle is used.

The hydrophilicization is carried out, e.g., by providing a titanium oxide layer on the outermost layer of the substrate.

(Embodiment 9)

An organic photoelectric conversion element according to a further embodiment of implementation of the invention will be described hereinafter.

The configuration of the organic photoelectric conversion element according to the present embodiment is the same as shown in FIG. 4. The organic photoelectric conversion element according to the present embodiment is different from the related art organic photoelectric conversion element in that an electron-donating layer 4 and an electron-accepting layer 5 comprising fullerenes and/or carbon nanotubes incorporated therein are formed on a substrate or electrode having predetermined optical properties, surface profile, temperature properties and mechanical properties.

Fullerenes and carbon nanotubes have very high electron-accepting properties and thus can receive efficiently carriers from electron-donating organic materials. Thus, the formation of a photoelectric conversion region having such an electron-accepting layer on a substrate as defined in Embodiments 1 to 8 makes it possible to invariably provide an organic photoelectric conversion element having a higher conversion efficiency.

Further, a high efficiency organic photoelectric conversion element can be obtained also by making the photoelectric conversion region from a mixture of the electron-donating organic material and the electron-accepting material.

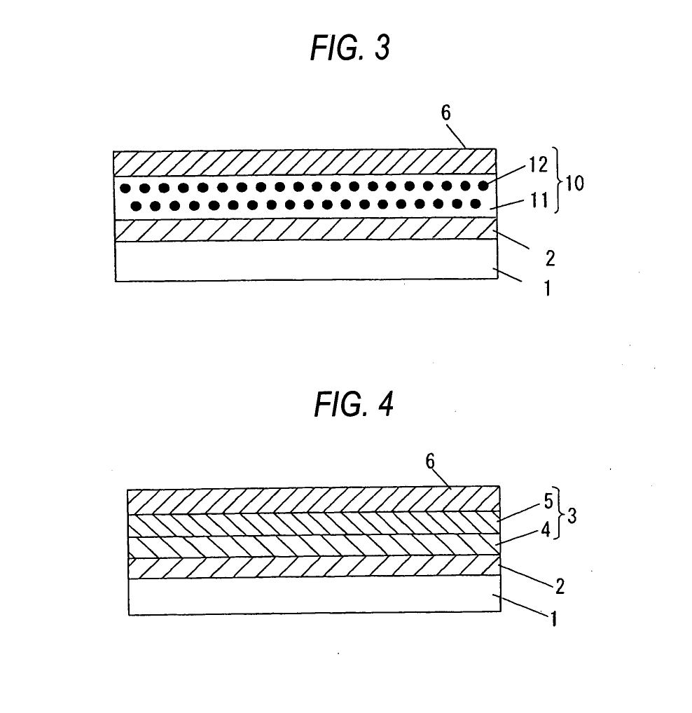

FIG. 3 is a sectional view of an essential part of an organic photoelectric conversion element according to a further embodiment of implementation of the invention.

FIG. 3 is the same as FIG. 4 in that it has a substrate 1, an anode 2 and a cathode 6. The organic photoelectric conversion element according to the present embodiment is different from the related art organic photoelectric conversion element in that the photoelectric conversion region 10 made of a mixture of the electron-donating organic material 11 and the electron-accepting material 12 is formed on a substrate or electrode having predetermined optical properties, surface profile, temperature properties and mechanical properties.

The term “mixture” as used herein is meant to indicate liquid or solid materials which have been mixed with each other by stirring or other operation in a vessel optionally with a solvent added, including a film formed by subjecting the mixture to spin coating.

It is known that such a mixed type organic photoelectric conversion element can perform light absorption, excitation and transfer of electron to accomplish a relatively high conversion efficiency despite its very simple structure. The use of a substrate as defined in Embodiments 1 to 8 makes it possible to provide an organic photoelectric conversion element having a further enhancement of conversion efficiency and reliability.

### EXAMPLE

### Example 1

Glass substrates having a visible light transmittance of 50% and 90%, respectively, were each subjected to sputtering to form an ITO layer to a thickness of 150 nm. A resist material (OFPR-800 (trade name), produced byTOKYO OHKA KOGYO CO., LTD.) was spread over the top of ITO layer by a spin coating method to form a resist layer thereon to a thickness of 5 μm. The resist layer was masked, exposed to light, and then developed so that it was patterned in a predetermined shape. Subsequently, these glass substrates were each dipped in a 60° C. 18N aqueous solution of hydrochloric acid so that ITO layer was etched on the area free of resist layer. These glass substrates were each washed with water, and then eventually freed of resist layer to obtain glass substrates comprising a first electrode made of ITO layer having a predetermined pattern but having different visible light transmittances. These substrates combined with ITO electrode exhibited a visible light transmittance of 45% and 81%, respectively.

Subsequently, these glass substrates were each sequentially subjected to ultrasonic cleaning with a detergent (Semicoclean (trade name), produced by Furuuchi Chemical corporation) for 5 minutes, ultrasonic cleaning with purified water for 10 minutes, ultrasonic cleaning with a solution obtained by mixing aqueous ammonia, aqueous hydrogen peroxide and water at a ratio of 1:1:5 (by volume) for 5 minutes and ultrasonic cleaning with 70° C. purified water for 5 minutes, blown with nitrogen to remove water content therefrom, and then heated to 250° C. so that it was dried.

Subsequently, a poly(3,4)ethylenedioxythiophene/polystyrene sulfonate (PEDT/PSS) was dropped onto these substrates through a filter having a pore diameter of 0.45 μm so that it was uniformly spread over these substrates using a spin coating method. These substrates were each then heated to 200° C. in a clean oven for 10 minutes to form a buffer layer thereon.

Subsequently, a chlorobenzene solution of a 1:4 (by weight) mixture of a poly(2-methoxy-5-(2′-ethyl hexyloxy)-1,4-phenylenevinylene) (MEH-PPV) and [5,6]-phenyl C61 butyric aid methyl ester ([5, 6]-PCBM) was spread over these substrates by a spin coating method. These substrates were each subjected to heat treatment at 100° C. in a clean oven for 30 minutes to form a photoelectric conversion region to a thickness of about 100 nm.

Finally, these substrates were each processed in a resistance-heated vacuum metallizer the pressure in which had been reduced to 0.27 mPa (=2×10⁻⁶ Torr) or less so that a LiF layer and an Al layer were sequentially formed on the top of the photoelectric conversion region to a thickness of about 1 nm and about 10 nm, respectively, to obtain organic photoelectric conversion elements.

A glass substrate was then bonded to the top of these organic photoelectric conversion elements with a photo-setting epoxy resin to obtain organic photoelectric conversion elements which are not subject to penetration of water content.

The results of evaluation of the photoelectric conversion properties of these elements are set forth in Table 1 below.

TABLE 1

| | Visible light | | |
|---|---|---|---|
| Visible light | transmittance of | | |
| transmittance | substrate + ITO | | |
| substrate (%) | electrode (%) | Voc (V) | Jsc (mA/cm²) |
| 90 | 81 | 0.82 | 5.1 |
| 50 | 45 | 0.80 | 3.2 |

When irradiated with light at an air mass of 1.5 (AM1.5), the element comprising the glass substrate having a visible light transmittance of 90% exhibited an open circuit voltage Voc of 0.82 V and a shortcircuit current Jsc as great as 5.1 mA/cm².

On the contrary, the element comprising the glass substrate having a visible light transmittance of 50% showed little difference in open circuit voltage from the other element but showed a shortcircuit current Jsc as drastically small as 3.2 mA/cm². This demonstrates that the use of a substrate having a high visible light transmittance makes it possible to obtain a high conversion efficiency.

### Example 2

Organic photoelectric conversion elements comprising a substrate made of a polymethyl methacrylate and a polycarbonate, respectively, were prepared in the same manner as in Example 1. Thereafter, these elements were each irradiated with ultraviolet rays under a high voltage mercury lamp having a luminance of 100 mJ/cm² for 10 hours. The conversion efficiency of these elements were each then compared with the initial value. The results are set forth in Table 2 below.

TABLE 2

| | Conversion efficiency after |
|---|---|
| | ultraviolet ray irradiation |
| | test/initial conversion |
| Substrate | efficiency |
| Polymethyl methacrylate | 0.9 |
| Polycarbonate | 0.6 |

The element comprising a polymethyl methacrylate impermeable to light in the ultraviolet range showed no great deterioration of properties. On the contrary, the element comprising a polycarbonate permeable to light in the ultraviolet range showed a drastic deterioration of properties.

It is thus made obvious that when the substrate is impermeable to light in the ultraviolet range, the deterioration of conversion properties can be prevented.

### Example 3

A test was made on the thermal stability of substrates.

Elements comprising a substrate made of a polycarbonate having a high glass transition point and softening temperature, a polymethyl methacrylate having a high glass transition point and softening temperature and a polyethylene having a low glass transition point and softening temperature, respectively, were prepared in the same manner as in Example 1. These elements were each evaluated for stability at the step of forming ITO layer and tested for the effect of 500 hours of storage at a temperature as high as 60° C. The results are set forth in Table 3 below.

TABLE 3

| | Stability in ITO | |
|---|---|---|
| Substrate | layer formation | Heat resistance |
| Polymethyl | Good | Good |
| methacrylate | | |
| Polycarbonate | Good | Good |
| Polyethylene | Poor | — |

The polymethyl methacrylate and a polycarbonate having a high glass transition point and softening temperature underwent no deformation even at the ITO layer forming step where they are exposed to high temperature. On the contrary, when the polyethylene film having a low heat resistance was used, the base film underwent softening when heated at the ITO layer forming step, making it impossible to obtain a smooth ITO substrate and prepare an element.

Organic photoelectric conversion elements formed on the heat-resistant base films, i.e., polycarbonate and polymethyl methacrylate allowing the formation of ITO layer were each operated at a temperature as high as 60° C. for 500 hours. As a result, none of these elements were observed to show a drop of conversion efficiency probably due to deformation of substrate. Thus, these elements were considered excellent.

### Example 4

Organic photoelectric conversion elements comprising a substrate made of a polycarbonate having a high flexibility, a polyethylene terephthalate having a high flexibility and a polystyrene having a low flexibility, respectively, were prepared in the same manner as in Example 1. Subsequently, these elements were each deformed into a cylinder having a radius of 1 cm which was then evaluated to see if it has a photoelectric conversion capacity. The results are set forth in Table 4 below.

TABLE 4

| Substrate | Flex properties of element |
|---|---|
| Polyethylene terephthalate | Good |
| Polycarbonate | Good |
| Polystyrene | Poor |

As a result, the elements comprising a substrate made of polycarbonate and polyethylene terephthalate which are great in both tensile strength and maximum elongation, respectively, were able to perform photoelectric conversion without causing clouding of film due to necking. On the contrary, when bent, the element comprising a substrate made of polystyrene underwent destruction of the substrate itself and could no longer perform photoelectric conversion.

In accordance with the invention, the optimization of the optical, thermal and mechanical properties of the substrate to be incorporated in the organic photoelectric conversion element makes it possible to provide an organic photoelectric conversion element which can be used in various atmospheres and thus can invariably supply electricity.

### CROSS REFERENCE TO RELATED APPLICATION

This application is based upon and claims the benefit of priority of Japanese Patent Application No. 2003-194212 filed on Jul. 9, 2003, the contents of which are incorporated herein by reference in its entirety.

1. An organic photoelectric conversion element comprising:
at least two electrodes on a substrate; and
a photoelectric conversion region provided between the electrodes, having at least one electron-donating organic material and one electron-accepting material,
wherein the visible light transmittance of the substrate is not less than 85% or
a product of the visible light transmittance of the substrate and one of the electrodes formed on the substrate is not less than 80%.

2. An organic photoelectric conversion element as claimed in claim 1, wherein the maximum light transmittance of the substrate and one of the electrodes formed on the substrate are each not less than 85% and the maximum light transmittance of the electrode substrate comprising the substrate and one of the electrodes formed on the substrate in combination is not less than 80%.

3. An organic photoelectric conversion element as claimed in claim 1, wherein haze value of the substrate is not more than 30%.

4. An organic photoelectric conversion element comprising:
at least two electrodes on a substrate; and
a photoelectric conversion region provided between the electrodes, having at least one electron-donating organic material and one electron-accepting material,
wherein the refractive index of the substrate increases toward the direction of transmission of light from the direction of incidence of light.

5. An organic photoelectric conversion element comprising:
at least two electrodes on a substrate; and
a photoelectric conversion region provided between the electrodes, having at least one electron-donating organic material and one electron-accepting material,
wherein the substrate is flexible.

6. The organic photoelectric conversion element as defined in claim 5, wherein the flexible substrate is made of a light-transmitting organic material.

7. An organic photoelectric conversion element comprising:
at least two electrodes on a substrate; and
a photoelectric conversion region provided between the electrodes, having at least one electron-donating organic material and one electron-accepting material,
wherein the substrate is impermeable to light in the ultraviolet range.

8. An organic photoelectric conversion element as claimed in claim 7, wherein the substrate is resistant to exposure to ultraviolet rays.

9. An organic photoelectric conversion element comprising:
at least two electrodes on a substrate; and
a photoelectric conversion region provided between the electrodes, having at least one electron-donating organic material and one electron-accepting material,
wherein the maximum height Rmax (JIS B 0601) of the surface roughness of the substrate and/or the electrodes formed on the substrate is 100 nm or less.

10. An organic photoelectric conversion element as claimed in claim 9, wherein the arithmetic average roughness Ra of the surface of the substrate and/or the electrodes formed on the substrate is from 0.01 nm to 10 nm.

11. An organic photoelectric conversion element as claimed in claim 9, wherein the total number of foreign matters, depression, etc. having a diameter of 1 μm or more on the surface of the substrate and/or the electrodes formed on the substrate is 100 or less per m².

12. An organic photoelectric conversion element comprising:
at least two electrodes on a substrate; and
a photoelectric conversion region provided between the electrodes, having at least one electron-donating organic material and one electron-accepting material,
wherein the substrate is subjected to heat treatment before the formation of the organic photoelectric conversion element.

13. An organic photoelectric conversion element as claimed in claim 6, wherein the glass transition point of the substrate is 80° C. or more.

14. An organic photoelectric conversion element as claimed in claim 6, wherein the deflection temperature under load (DTUL) (=softening temperature) of the substrate is 60° C. or more.

15. An organic photoelectric conversion element as claimed in claim 6, wherein the substrate exhibits a tensile strength (JIS K 6911) of 30 N·mm⁻² or more and a maximum elongation (JIS K 7113) of 50% or more.

16. An organic photoelectric conversion element comprising:
at least two electrodes on a substrate; and
a photoelectric conversion region provided between the electrodes, having at least one electron-donating organic material and one electron-accepting material,
wherein the outer surface of the substrate is hydrophilicized.

17. An organic photoelectric conversion element as claimed in claim 1, wherein the electron-accepting material comprises fullerenes and/or carbon nanotubes incorporated therein.

18. An organic photoelectric conversion element as claimed in claim 1, wherein the electron-donative organic material and the electron-accepting material are provided in admixture.
